(19) United States
(12) Patent Application Publication
(10) Pub. No.: US 2003/0183944 A1
(43) Pub. Date: Oct. 2, 2003

(54) Semiconductor device and manufacturing method for the same, circuit board, and electronic device

(76) Inventor: Jun Taniguchi, Sakata-shi (JP)

Correspondence Address: EPSON RESEARCH AND DEVELOPMENT INC, INTELLECTUAL PROPERTY DEPT, 150 RIVER OAKS PARKWAY, SUITE 225, SAN JOSE, CA, 95134, US

(21) Appl. No.: 10/368,101

(22) Filed: Feb. 18, 2003

(30) Foreign Application Priority Data
Feb. 21, 2002 (JP) 2002-044930

(51) Int. Cl. H01L 23/48

(52) U.S. Cl. 257/777

(57) ABSTRACT

A semiconductor device features excellent mountability without limiting the arrangement of external contacts, a manufacturing method for such a semiconductor device, a circuit board, and an electronic device. The semiconductor device includes a substrate having first wiring pattern, external contacts formed on the substrate, a first semiconductor chip with second wiring pattern that is bonded face-down to the substrate, and a second semiconductor chip bonded face-down to the first semiconductor chip.

### BACKGROUND OF THE INVENTION

1. Field of the Invention

The present invention relates to a semiconductor device and a manufacturing method for the same, a circuit board, and an electronic device.

2. Description of the Related Art

CSP (chip size/scale package) semiconductor devices having many semiconductor chips include constructions having semiconductor chips mounted on both sides of a substrate, and constructions having semiconductor chips and the substrate connected with wire bonding.

A problem with constructions having semiconductor chips mounted on both sides of the substrate is that the arrangement of the external pins of the semiconductor device is limited. Furthermore, with constructions in which the semiconductor chips and substrate are connected by wire bonding, the size of the semiconductor device increases and a further mold sealing step is required.

### OBJECTS OF THE INVENTION

It is therefore an object of the present invention to solve these problems.

It is another object of this invention to provide a semiconductor device and manufacturing method for the same, a circuit board, and an electronic device having excellent mountability and being substantially free of limitations on the arrangement of external pins.

### SUMMARY OF THE INVENTION

According to one aspect of the invention, a semiconductor device is provided. The semiconductor device comprises a substrate having a first surface and a second surface; a first wiring pattern formed on the first surface of the substrate; a plurality of external contacts formed on the second surface of the substrate and electrically connected to the first wiring pattern; a first semiconductor chip having a face-down surface that is bonded to the first surface of the substrate and electrically connected to the first wiring pattern; a second wiring pattern formed on the face-down surface of the first semiconductor chip; and a second semiconductor chip bonded to the face-down surface of the first semiconductor chip and electrically connected to the second wiring pattern, the second semiconductor chip being disposed between the first semiconductor chip and the substrate.

By disposing the second semiconductor chip between the first semiconductor chip and substrate the size of the semiconductor device is reduced. Furthermore, by having the external contacts on a surface of the substrate to which no semiconductor chip is bonded, the arrangement of the external contacts is not so limited. Rather, the location of the external contacts can be more freely chosen.

Preferably, at least one of the plurality of external contacts is formed in an area where the first and second semiconductor chips overlap. This enables the external contacts to be formed within the area of the second semiconductor chip.

Preferably, in this semiconductor device, an underfill material is disposed between the first semiconductor chip and substrate. By filling an underfill material between the first semiconductor chip and substrate, a separate process for mold sealing the second semiconductor chip is unnecessary. With this configuration the connection between the first semiconductor chip and the second semiconductor chip or substrate can be protected.

Preferably, in this semiconductor device, a recess is formed in the first surface of the substrate, and the second semiconductor chip is positioned in the recess. With this configuration contact between the substrate and first wiring pattern and the second semiconductor chip can be avoided.

Another aspect of the invention involves a circuit board having a semiconductor device as described above mounted thereto.

A further aspect of the invention involves an electronic device having a semiconductor device as described above.

According to a still further aspect of the invention, a method for manufacturing a semiconductor device is provided. The method includes bonding a first wiring pattern to a first surface of a substrate; forming a plurality of external contacts on a second surface of the substrate; bonding a second wiring pattern to a face-down surface of a first semiconductor chip; mounting a second semiconductor chip on the face-down surface of the first semiconductor chip; and mounting the face-down surface of the first semiconductor chip to the first surface of the substrate, such that the second semiconductor chip is disposed between the first semiconductor chip and the substrate. The first wiring pattern is electrically connected to the external contacts and to the first semiconductor chip, and the second wiring pattern is electrically connected to the second semiconductor chip.

With this aspect of the invention, the second semiconductor chip is disposed between a first semiconductor chip and substrate. The size of the semiconductor device can therefore be reduced. Also, by forming the external contacts on a surface of the substrate to which no semiconductor chip is bonded, the arrangement of the external contacts is not so limited. Rather, the location of the external contacts can be more freely chosen.

In this semiconductor device manufacturing method preferably at least one of the plural external contacts is formed in an area where the first and second semiconductor chips overlap. This enables the external contacts to be formed within the area of the second semiconductor chip.

This semiconductor device manufacturing method can further include disposing an underfill material between the first semiconductor chip and substrate. By filling an underfill material between the first semiconductor chip and substrate, a separate process for mold sealing the second semiconductor chip can be omitted. This makes it possible to protect the connection between the first semiconductor chip and the second semiconductor chip or substrate.

In this semiconductor device manufacturing method the underfill material can be disposed between the first semiconductor chip and second semiconductor chip, and between the first semiconductor chip and substrate, in a single step. Productivity can be thus be improved.

In this semiconductor device manufacturing method the first surface of the substrate preferably has a recess in which the second semiconductor chip is disposed. The second semiconductor chip can thus be prevented from contacting the substrate and first wiring pattern.

Other objects and attainments together with a fuller understanding of the invention will become apparent and appreciated by referring to the following description and claims taken in conjunction with the accompanying drawings.

### BRIEF DESCRIPTION OF THE DRAWINGS

FIG. 1 shows a semiconductor device according to a first embodiment of the present invention;

FIG. 2 shows a semiconductor device according to a second embodiment of the present invention;

FIG. 3 shows a circuit board according to embodiments of the present invention;

FIG. 4 shows an electronic device according to embodiments of the present invention; and

FIG. 5 shows an electronic device according to embodiments of the present invention.

### DESCRIPTION OF THE PREFERRED EMBODIMENTS

Preferred embodiments of the present invention are described below with reference to the accompanying figures. These embodiments are provided by way of example and are not intended to limit the scope of the present invention.

First Embodiment

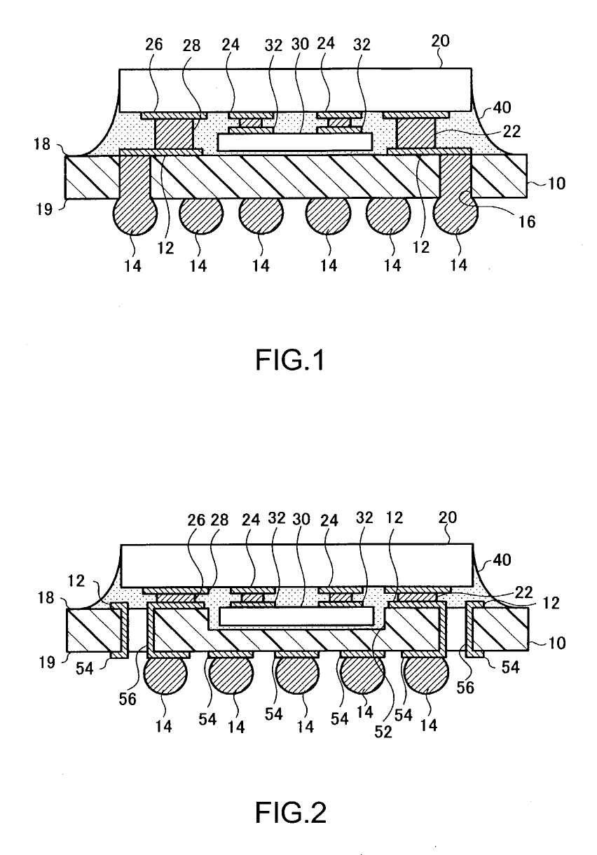

FIG. 1 shows a semiconductor device according to a preferred embodiment of the present invention. A semiconductor device according to the present embodiment has a substrate 10, which may also be referred to as a wiring substrate or interposer. The planar shape of substrate 10 is generally rectangular, but shall not be so limited. Moreover, the overall shape of the substrate 10 is not specifically limited, nor is the thickness of the substrate 10.

The substrate 10 can be made from an organic or inorganic material, or a combination of such materials. A substrate or film of polyethylene terephthalate (PET), for example, can be used as the substrate 10. Alternatively, a flexible circuit board made of a polyimide resin can be used as the substrate 10. A FPC (flexible printed circuit) or a tape used in TAB (tape automated bonding) methods could also be used as the flexible circuit board. Examples of a substrate 10 made from an inorganic material include ceramic substrates and glass substrates. A glass epoxy substrate is an example of a hybrid structure of organic and inorganic materials.

A first wiring pattern 12 is formed on a first surface 18 of the substrate 10. The first wiring pattern 12 can be formed, for example, by affixing a copper foil or other metal foil to the substrate 10 using an intervening adhesive material not shown in the figure, and then etching after applying a photolithography process. This forms a three-layer substrate. It is also possible to form a two-layer substrate by forming the first wiring pattern 12 on the substrate 10 without using an adhesive material. The first wiring pattern 12 can, for example, be formed with sputtering. An additive method forming the first wiring pattern 12 by electroless plating can alternatively be used. The first wiring pattern 12 can also have lands. An insulation film can also be formed on the first wiring pattern 12 avoiding the parts where electrical connection to the first wiring pattern is made.

External contacts 14 are formed on the substrate 10, preferably to the side of the substrate 10 on a second surface 19 that is opposite the first surface 18. The external contacts 14 can be solder balls. Alternatively, part of the first wiring pattern 12 can be bent through a through-hole 16 to form the external contacts 14. The external contacts 14 are electrically connected to the first wiring pattern 12. In the example shown in FIG. 1 the first wiring pattern 12 and external contacts 14 are electrically connected through the through-hole 16.

Because there are no semiconductor chips formed on the second surface 19 side of the substrate 10, the external contacts 14 can be formed anywhere on the second surface 19 of the substrate 10. In the example shown in FIG. 1, the external contacts 14 are formed only inside the mounting area of the substrate 10 in the example shown in FIG. 1, making this semiconductor device a fan-in type. Alternatively, the external contacts 14 can be formed only outside the mounting area of a first semiconductor chip 20 as in a fan-out type device. It is also possible to form the external contacts 14 both inside and outside the area of the first semiconductor chip 20 as in a fan-in/out type device.

The first semiconductor chip 20 is, for example, flash memory, SRAM, DRAM, ASIC, MPU, or other type of device. The combination of first semiconductor chip 20 and a second semiconductor chip 30 further described below can be, for example, both SRAM devices, both DRAM devices, or flash memory and SRAM devices. The planar shape of the first semiconductor chip 20 is usually rectangular (a square or a rectangle). A plurality of first contacts 22 and second wiring pattern 24 are formed on one surface (i.e., an active surface) of the first semiconductor chip 20. A passivation film not shown in the figure can also be formed on the active surface of the first semiconductor chip 20. The passivation film can be formed of, for example, SiO₂, SiN, or polyimide resin.

First contacts 22 are formed on the first semiconductor chip 20. The first contacts 22 can be arranged along at least one side (in many cases two or four parallel sides) on the active surface of the first semiconductor chip 20. The first contacts 22 may be formed avoiding the mounting area of the second semiconductor chip 30, or they could be formed so as to enclose the mounting area of the second semiconductor chip 30. The first contacts 22 shown in FIG. include pads 26 and bumps 28. The pads 26 can be made thin and flat on the first semiconductor chip 20 from aluminum or copper, for example. The bumps 28 can be formed by electroless plating, or they could be wire bonding bumps. Nickel, chrome, titanium, or other material can be added as a bump metal diffusion prevention layer between the pads 26 and bumps 28. Alternatively, the bumps 28 can be omitted and contacts 22 formed with just the pads. Furthermore, the height of the first contacts 22 can be set so that the second semiconductor chip 30 does not contact the substrate 10 or first wiring pattern 12.

A second wiring pattern 24 is formed on the first semiconductor chip 20. The second wiring pattern 24 can be formed over the passivation layer (not shown in the figure) disposed to the active surface of the first semiconductor chip 20. The second wiring pattern 24 can be formed with a process identical to the process used to form the first wiring pattern 12.

As previously noted, the semiconductor device according to this embodiment of the invention also includes a second semiconductor chip 30. The content of the second semiconductor chip 30 is the same as the first semiconductor chip 20. The second semiconductor chip 30 is usually rectangular. The second semiconductor chip 30 has multiple second contacts 32, and these second contacts 32 are formed on one surface (the active surface) of the second semiconductor chip 30. The second contacts 32 are formed on at least one side (in many cases on two or four parallel sides) of the second semiconductor chip 30. The height of the second contacts 32 can be set so that the second semiconductor chip 30 does not contact the substrate 10 or first wiring pattern 12.

In this preferred embodiment of the invention the second semiconductor chip 30 is mounted by face-down bonding (flip-chip mounting) to the first semiconductor chip 20. The second contacts 32 and second wiring pattern 24 are electrically connected.

In this embodiment of the invention the first semiconductor chip 20 to which the second semiconductor chip 30 is mounted is bonded face-down (flip-chip mounted) to the substrate 10. The first contacts 22 and first wiring pattern 12 are electrically connected.

In a semiconductor device according to the present invention the second semiconductor chip 30 is located between the substrate 10 and first semiconductor chip 20. As a result a thinner semiconductor device can be achieved. Furthermore, because the second semiconductor chip 30 and first semiconductor chip 20 are bonded face-down (flip-chip mounted), it is not necessary to allow for electrical connection using wire, and a mold sealing process is unnecessary.

An underfill material 40 may be disposed between the substrate 10 and first semiconductor chip 20. The underfill material 40 can be an adhesive provided in liquid or gel form, or an adhesive sheet provided in sheet form. The adhesive can be a material of which the primary constituent is an epoxy resin, or an insulating material such as a NCF (non-conductive film) or NCP (nonconductive paste).

The underfill material 40 can also be an anistropic conductive adhesive (ACA) in which conductive particles are dispersed, such as an anistropic conductive film (ACF) or anistropic conductive paste (ACP), for example. An anistropic conductive adhesive has a dispersion of conductive particles (filler) in a binder, and a dispersant is sometimes added. A thermosetting adhesive is often used as the binder of the anistropic conductive adhesive.

At least the area of the substrate 10 where the underfill material 40 is disposed can be a rough surface. That is, the surface of the substrate 10 could be roughened mechanically using sandblasting, physically using plasma, UV light, or ozone, for example, or chemically using an etchant. By thus increasing the bonding area of the substrate 10 and underfill material 40, physical and chemical adhesion can be increased and a stronger bond can be formed between them. The electrical connection reliability of the semiconductor device can also be improved by using the shrinkage force of the underfill material 40 to press the first wiring pattern 12 and first contacts 22 together and press the second wiring pattern 24 and second contacts 32 together.

A semiconductor device according to this embodiment of the invention is configured as described above, and a manufacturing method for the same is described below.

A substrate 10 having the above-described first wiring pattern 12 and external contacts 14 formed thereon, a first semiconductor chip 20 having the first contacts 22 and second wiring pattern 24 formed, and a second semiconductor chip 30 having the second contacts 32 formed, are first prepared.

A semiconductor device according to the present invention can be obtained by mounting the second semiconductor chip 30 to the first semiconductor chip 20 in a first process, then mounting the first semiconductor chip 20 to the substrate 10 in a second process, and lastly imparting the underfill material 40.

Face-down bonding and flip-chip mounting can be used in the first process and second process. Any of various methods can be used for face-down bonding, including metallic bonding using Au—Au, Au—Sn, or solder, for example, or methods using the shrinkage force of an insulating resin.

In this embodiment of the invention the second semiconductor chip 30 is mounted to the first semiconductor chip 20, the first semiconductor chip 20 is mounted to the substrate 10, and the underfill material 40 is then imparted. The underfill material 40 can therefore be disposed in a single process.

Second Embodiment

FIG. 2 illustrates a semiconductor device according to a second embodiment of the present invention. It should be noted that much of the above description of the first embodiment is also applicable to this embodiment.

In accordance with this second embodiment, a recess 52 is formed in the substrate 10 of the present embodiment. This recess 52 is formed in the first surface of the substrate 10. Neither the shape nor the depth of the recess 52 is specifically limited. A semiconductor device according to this embodiment of the invention enables a second semiconductor chip 30 disposed between the substrate 10 and first semiconductor chip 20 to be placed in the recess-52. As a result, the semiconductor device can be made thinner.

A first wiring pattern 12 is formed to the substrate 10 of this embodiment. This first wiring pattern 12 can be formed avoiding the recess 52.

Also, in accordance with the second embodiment, a third wiring pattern 54 can be formed to the substrate 10 of the present embodiment. The third wiring pattern 54 can be formed on the second surface 19 side of the substrate 10 using a process identical to the process forming the first wiring pattern 12 or second wiring pattern 24. The third wiring pattern 54 is electrically connected to the first wiring pattern 12. In the example shown in FIG. 2 a through-hole 56 is formed to the substrate 10, and the third wiring pattern 54 is electrically connected to the first wiring pattern 12 through the through-hole 56. An insulation film can be formed to the surface of the third wiring pattern 54 avoiding the part contacting the external contacts 14.

External contacts 14 are formed to the substrate 10 of this embodiment. In the example shown in FIG. 2 the external contacts 14 are formed on the third wiring pattern 54, and are electrically connected to the first wiring pattern 12 through the third wiring pattern 54. The external contacts 14 can, however, alternatively directly contact the first wiring pattern 12 through a through-hole, as shown in FIG. 1 in connection with the first embodiment.

Also, in a semiconductor device according to this embodiment of the invention either the first semiconductor chip 20 or the second semiconductor chip 30 can be mounted to the second surface 19 of the substrate 10. The third wiring pattern 54 and external contacts 14 can therefore be formed anywhere on the second surface 19 side of the substrate 10. By using the third wiring pattern 54 to electrically connect the first wiring pattern 12 and external contacts 14, the external contacts 14 can be located without being affected by the position of the recess 52.

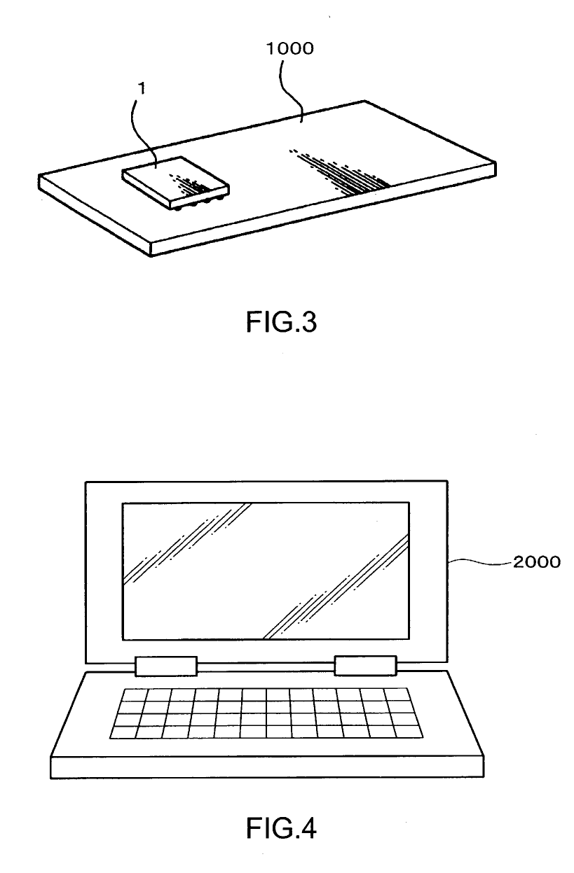

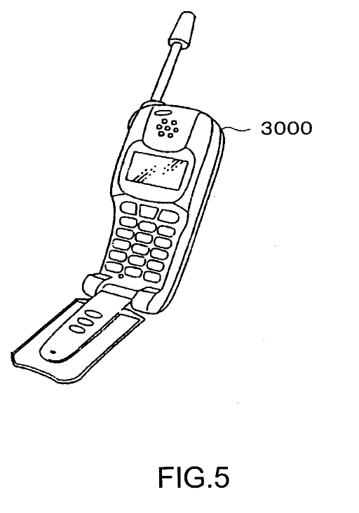

A circuit board 1000 to which a semiconductor device 1, constructed according to an embodiment of the invention, is mounted is shown in FIG. 3. A notebook type personal computer 2000 is shown in FIG. 4, and a cell phone 3000 is shown in FIG. 5 as examples of an electronic device having a semiconductor device according to an embodiment of the present invention.

While the invention has been described in conjunction with several specific embodiments, many further alternatives, modifications, variations and applications will be apparent to those skilled in the art that in light of the foregoing description. Thus, the invention described herein is intended to embrace all such alternatives, modifications, variations and applications as may fall within the spirit and scope of the appended claims.

For example, the present invention includes similar configurations having the same function, method, and result, as well as similar configurations having the same operational effect, within the scope of the claims. Furthermore, the present invention includes configurations wherein parts are substituted for parts described above but which still fall within the scope of the claims. Still further, the present invention includes configurations which add known technology to the configurations described in the above embodiments.

What is claimed is:

1. A semiconductor device, comprising:
a substrate having a first surface and a second surface;
a first wiring pattern formed on the first surface of the substrate;
a plurality of external contacts formed on the second surface of the substrate and electrically connected to the first wiring pattern;
a first semiconductor chip having a face-down surface that is bonded to the first surface of the substrate and electrically connected to the first wiring pattern;
a second wiring pattern formed on the face-down surface of the first semiconductor chip; and
a second semiconductor chip bonded to the face-down surface of the first semiconductor chip and electrically connected to the second wiring pattern, the second semiconductor chip being disposed between the first semiconductor chip and the substrate.

2. A semiconductor device as described in claim 1, wherein at least one of the plurality of external contacts is formed in an area where the first and second semiconductor chips overlap.

3. A semiconductor device as described in claim 1, further comprising an underfill material disposed between the first semiconductor chip and substrate.

4. A semiconductor device as described in claim 1, wherein a recess is formed in the first surface of the substrate, and the second semiconductor chip is positioned in the recess.

5. A circuit board, comprising:
a semiconductor device comprising
a substrate having a first surface and a second surface;
a first wiring pattern formed on the first surface of the substrate;
a plurality of external contacts formed on the second surface of the substrate and electrically connected to the first wiring pattern;
a first semiconductor chip having a face-down surface that is bonded to the first surface of the substrate and electrically connected to the first wiring pattern;
a second wiring pattern formed on the face-down surface of the first semiconductor chip; and
a second semiconductor chip bonded to the face-down surface of the first semiconductor chip and electrically connected to the second wiring pattern, the second semiconductor chip being disposed between the first semiconductor chip and the substrate.

6. An electronic device, comprising:
a semiconductor device comprising
a substrate having a first surface and a second surface;
a first wiring pattern formed on the first surface of the substrate;
a plurality of external contacts formed on the second surface of the substrate and electrically connected to the first wiring pattern;
a first semiconductor chip having a face-down surface that is bonded to the first surface of the substrate and electrically connected to the first wiring pattern;
a second wiring pattern formed on the face-down surface of the first semiconductor chip; and
a second semiconductor chip bonded to the face-down surface of the first semiconductor chip and electrically connected to the second wiring pattern, the second semiconductor chip being disposed between the first semiconductor chip and the substrate.

7. A method for manufacturing a semiconductor device, comprising:
bonding a first wiring pattern to a first surface of a substrate;
forming a plurality of external contacts on a second surface of the substrate;
bonding a second wiring pattern to a face-down surface of a first semiconductor chip;
mounting a second semiconductor chip on the face-down surface of the first semiconductor chip; and
mounting the face-down surface of the first semiconductor chip to the first surface of the substrate, such that the second semiconductor chip is disposed between the first semiconductor chip and the substrate;
wherein the first wiring pattern is electrically connected to the external contacts and to the first semiconductor chip; and
wherein the second wiring pattern is electrically connected to the second semiconductor chip.

8. A method as described in claim 7, wherein at least one of the plurality of external contacts is formed in an area where the first and second semiconductor chips overlap.

9. A method as described in claim 7, further comprising disposing an underfill material between the first semiconductor chip and the substrate.

10. A method as described in claim 7, comprising disposing an underfill material between the first semiconductor chip and the second semiconductor chip and between the first semiconductor chip and the substrate in a single process.

11. A method as described in claim 7, wherein the first surface of the substrate has a recess in which the second semiconductor chip is disposed.
